(19) United States
(12) Patent Application Publication
(10) Pub. No.: US 2015/0271957 A1
(43) Pub. Date: Sep. 24, 2015

(54) COOLING FLOW OPTIMIZATION

(71) Applicant: Hamilton Sundstrand Corporation, Windsor Locks, CT (US)

(72) Inventor: Debabrata Pal, Hoffman Estates, IL (US)

(73) Assignee: Hamilton Sundstrand Corporation, Windsor Locks, CT (US)

(21) Appl. No.: 14/220,274

(22) Filed: Mar. 20, 2014

(51) Int. Cl. H05K 7/20

(52) U.S. Cl. CPC H05K 7/20863; H05K 7/20945

(57) ABSTRACT

A remote power unit has an inlet duct and an outlet duct in a housing. The inlet and outlet ducts are configured to receive and expel cooling air from the remote power unit. A plurality of slots within the housing each hold a printed wiring board. A door is attached to each of the slots, and each door has a shape thermal memory element. The shape thermal memory element is used to open and close the doors to either allow or prevent cooling airflow from passing along the printed wiring board. In this way, cooling air use is reduced to only those areas where cooling is needed.

### BACKGROUND

Power distribution in aircraft often employs a series of printed wiring boards housed within a remote power unit. The power unit supplies power to each of the printed wiring boards, for example via a backplane. The printed wiring boards can contain circuitry to modify power output to any of a variety of applications requiring electricity throughout the aircraft.

Printed wiring boards dissipate some power as heat when routing electricity to a load elsewhere in the aircraft. In some cases, power dissipation of a printed wiring board can be as high as 20 to 60 Watts. The functionality and longevity of the printed wiring boards depends on adequate heat dissipation from the printed wiring boards. For this reason, cooling air is often routed through the power unit, and is directed around each of the printed wiring boards to provide cooling.

Such air cooling satisfactorily cools the printed wiring boards, but introduces inefficiency. For example, a subset of the devices powered by the printed wiring boards may be off at any given time. Those printed wiring boards configured to route power to a device that is powered down will not dissipate heat. Nonetheless, known air cooling systems route cooling air past those printed wiring boards. It is desirable to reduce the quantity of pressurized cooling air needed by the power unit, and cool only those printed wiring boards that are hot.

### SUMMARY

A remote power unit has an inlet duct and an outlet duct in a housing. The inlet and outlet ducts are configured to receive and expel cooling air from the remote power unit. A plurality of slots within the housing each hold a printed wiring board. A door is attached to each of the slots, and each door has a shape thermal memory element.

### BRIEF DESCRIPTION OF THE DRAWINGS

FIG. 1 is a cutaway perspective view of a remote power unit.

FIG. 2 is a cross-sectional view of the remote power unit of FIG. 1.

FIG. 3 is an exploded perspective view of a pair of slots each holding a printed wiring board and attached to a door.

FIG. 4 is a cross-sectional view of a slot and attached door.

FIG. 5 is a perspective view of an electrical connection between a printed wiring board and a hinge.

### DETAILED DESCRIPTION

A remote power unit contains several printed wiring boards (PWBs) that route power to loads throughout an aircraft or other system. The PWBs generate heat when delivering power to those loads, and cooling is required to prevent damage or failure that could be caused by overheating. A shape thermal memory alloy is used to open and close doors in the flowpath of a cooling airflow. As each PWB generates sufficient heat, that heat causes the shape memory element to open the door, and cooling airflow is routed along the PWB. Conversely, as the PWB cools, for example if it ceases delivering power to its corresponding remote load(s), the shape memory element closes the door and cooling airflow is blocked. This system reduces the use of cooling air, delivering cooling air only to those PWBs that are in need of cooling.

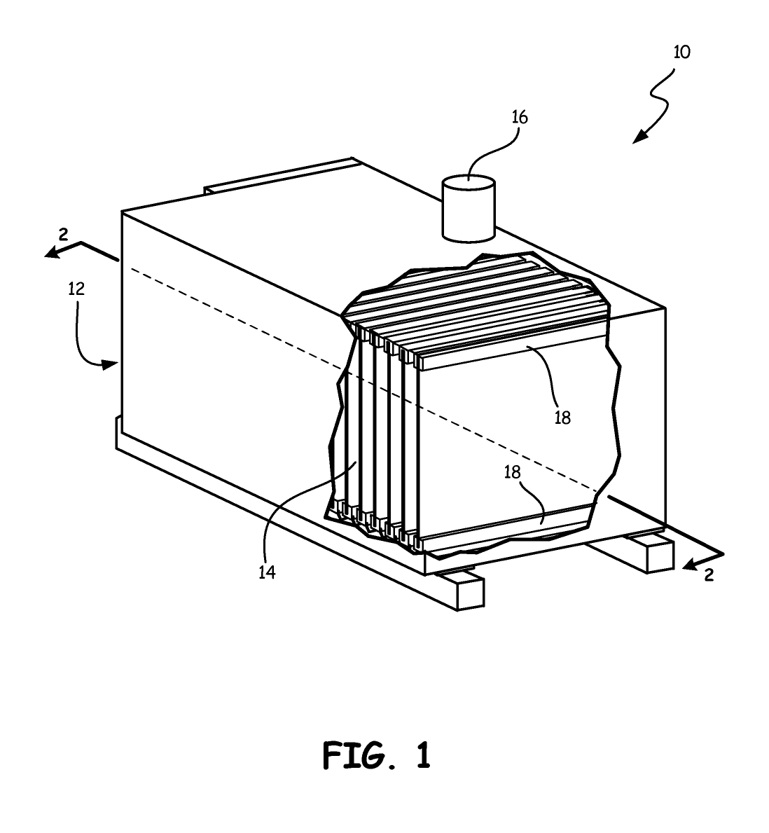

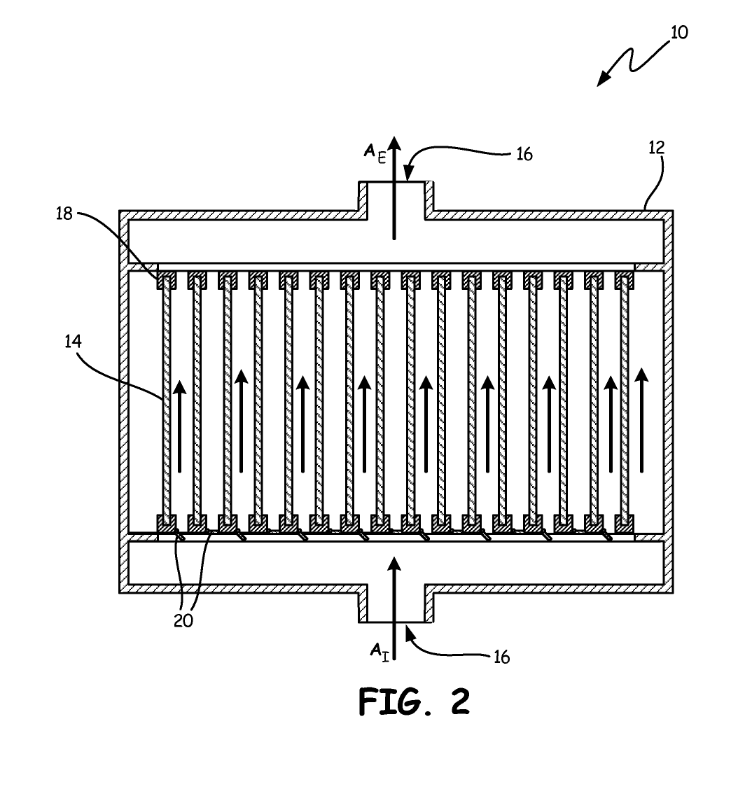

FIGS. 1-2 show remote power unit 10, which includes housing 12, PWBs 14, duct 16, slots 18, and doors 20. FIG. 1 is a cutaway perspective view of remote power unit 10. FIG. 2 is a cross-sectional view of remote power unit 10 taken along line 2-2 of FIG. 1.

Remote power unit 10 can be used in a variety of applications. In one embodiment, remote power unit 10 can be used to distribute power to various remote loads (not shown) in an aircraft. For example, various sensors, actuators, communication equipment, and/or other loads can be powered by remote power unit 10.

Housing 12 provides an outer shell for remote power unit 10. In FIG. 1, housing 12 is cut away to show the components housed therein. Housing 12 may include components to receive power from an external power source (not shown) and distribute that power to components it houses. For example, a gas turbine engine and associated generator may provide electric power to housing 12.

PWBs 14 are arranged within housing 12. As previously discussed, PWBs 14 are associated with one or more external loads (not shown). PWBs 14 are configured to receive electrical power through a backplane or other connection (not shown) and selectively route electrical power to associated loads only when needed. PWBs 14 generate some heat, typically as a result of power dissipation in the range of 20-60 W, while delivering power to one or more loads. When PWBs 14 are not delivering power to a load, they generate little or no heat.

Ducts 16 are arranged on housing 12, and provide access to the interior of remote power unit 10. One of ducts 16 is configured to allow inlet airstream A_{I} to enter housing 12. Similarly, one of ducts 16 is configured to allow egress airstream A_{E} to leave housing 12.

Slots 18 are positioned throughout housing 12 and are configured to receive PWBs 14. Slots 18 are substantially evenly spaced throughout housing 12. Slots 18 are in thermal contact with PWBs 14, such that as each PWB 14 heats up, the corresponding slot(s) 18 holding that PWB 14 are also heated.

Doors 20 are positioned on slots 18. In the embodiment shown, doors 20 are positioned on those slots 18 that are closer to duct 16 that contains inlet airstream A_{I} than their associated PWB 14 is. Doors 20 are positioned such that, in a closed configuration, the cooling air airstream is blocked. In the opened position, as indicated by arrows in FIG. 2, doors 20 permit a cooling airstream to pass along the corresponding PWB 14.

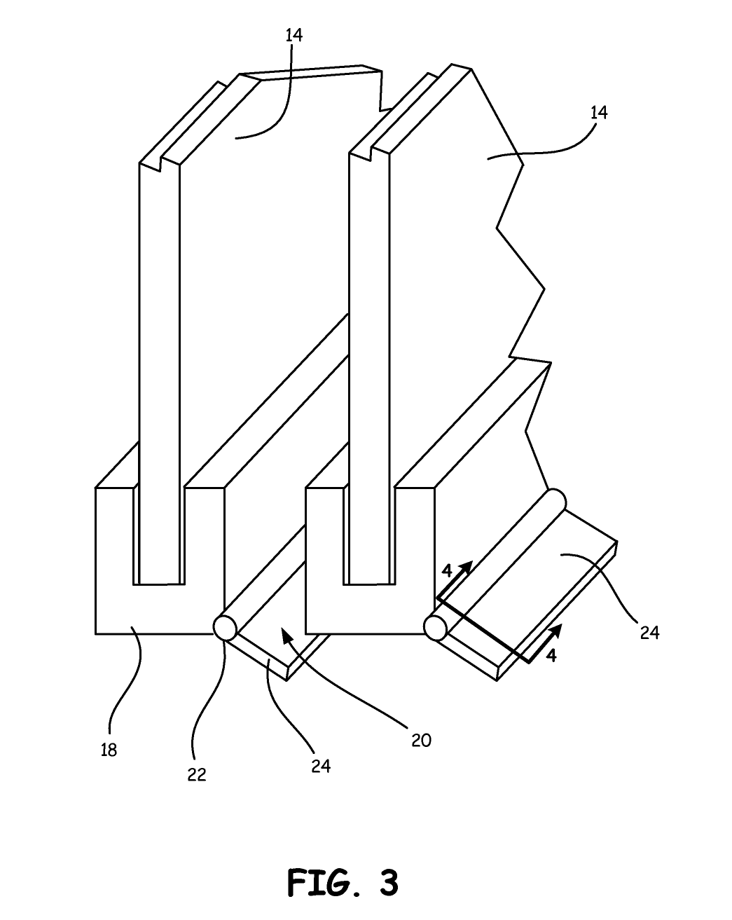

Some of doors 20 are at least partially open while others are closed, as shown in FIG. 2. In operation, some but not all of PWBs 14 are delivering power to a remote load at any given time. Those PWBs 14 that are delivering power generate heat, which causes doors 20 to open, as described in more detail with respect to FIGS. 3-5.

FIG. 3 is an exploded perspective view of a pair of slots 18 each holding a PWB 14 and attached to door 20. Door 20 includes hinge 22 and blocker 24.

Hinge 22 is a shape memory alloy hinge. For example, hinge 22 could be made of a Nitinol (nickel/titanium) alloy. Hinge 22 is thermally coupled with slot 18, which is in turn thermally coupled to PWB 14.

Blocker 24 is configured to be movable between a closed position and an open position. In the closed position, blocker 24 closes off the space between the adjacent slots 18. In the open position, blocker 24 permits cooling air to flow between adjacent slots 18.

Hinge 22 is affixed to slot 18 and blocker 24. Because hinge 22 is a shape memory element, it may change shape or size depending on the temperature. Below its transition temperature, hinge 22 has a shape and size that results in blocker 24 being interposed between adjacent slots 18 (i.e., blocking cooling air from passing between adjacent slots 18). Above its transition temperature, hinge 22 has a shape and size that does not cause blocker 24 to block the space between slots 18 (i.e., cooling air is routed between adjacent slots 18).

Opening and closing door 20 based on the temperature of its associated PWB 14 prevents waste of cooling air. By only opening those doors 20 that are associated with a PWB 14 above a threshold temperature, cooling air is delivered only to those PWBs 14 that need cooling, and draw of conditioned bleed air is minimized.

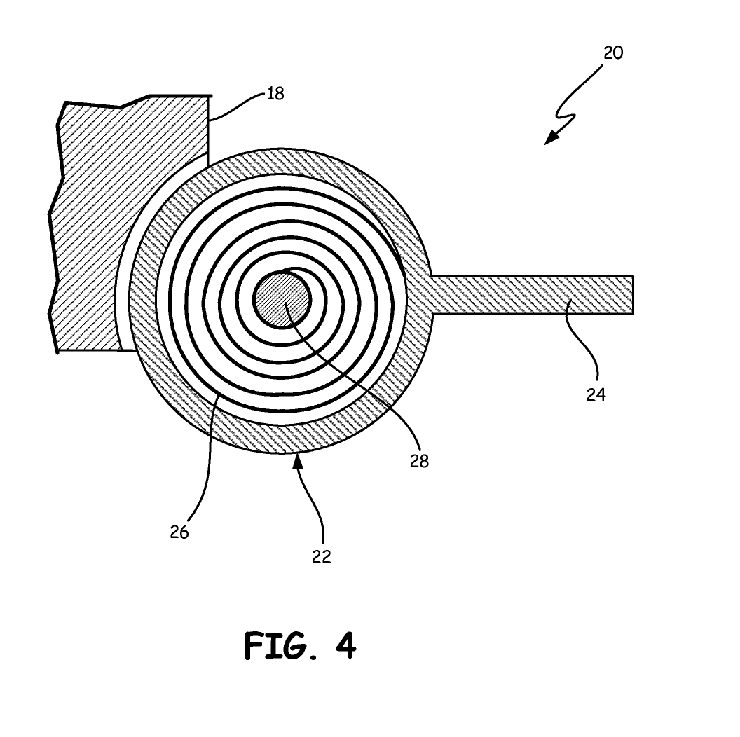

FIG. 4 is a cross-sectional view of a part of slot 18, as well as its corresponding door 20. Door 20 includes hinge 22 and blocker 24. The cross-section of FIG. 4 shows a part of hinge 22 that includes shape memory spring 26 and pin 28. As shown in FIG. 4, shape memory spring 26 is below its transition temperature and blocker 24 is in the closed position.

As previously described with respect to FIGS. 2-3, shape memory spring 26 is a shape memory element that is configured to open or close blocker 24. Shape memory spring 26 increases in length as its temperature increases above a transition temperature. As shown in FIG. 4, shape memory spring 26 is affixed to pin 28, which is stationary relative to slot 18. As shape memory spring 26 increases in length, blocker 24 is forced clockwise around pin 28 into the open position. This process is reversible; by subsequently cooling shape memory spring 26 below its transition temperature, blocker is pulled counterclockwise around pin 28 into the closed position.

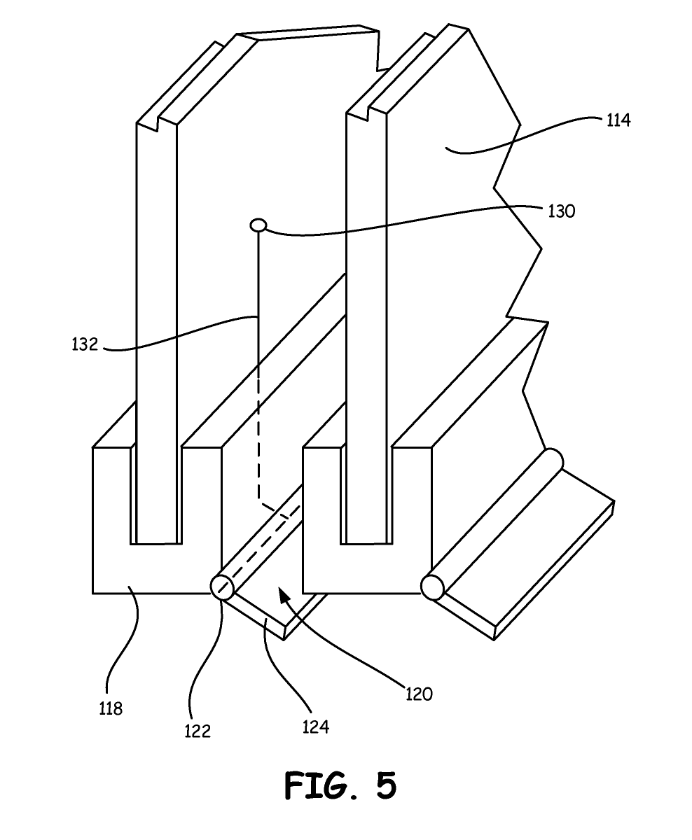

FIG. 5 is a perspective view of another embodiment of a cooling air blocking system. FIG. 5 shows a pair of printed wiring boards 114 each captured by a slot 118. Doors 120 each include a hinge 122 and a blocker 124. The embodiment illustrated in FIG. 5 also includes power source 130 and lead 132. Power source 130 delivers electricity to lead 132 when PWB 114 is delivering power to a remote load. Power source 130 supplies power to lead 132 when commanded by a temperature sensing and control circuit (not shown). For example, a temperature sensing and control unit may include at least one temperature sensor in the remote power unit, and a control circuit.

Lead 132 delivers that electricity to hinge 122, where it is used to operate blocker 124. For example, electricity dissipated in the form of heat (e.g., via resistive heating) to cause a thermal transition in a shape memory element, as described previously. In alternative embodiments, lead 132 may deliver power to a piezoelectric hinge, or any other actuator capable of opening and closing door 120 to provide a cooling air flow passage when desired.

Power source 130 delivers power to hinge 122 via lead 132 when current is flowing through PWB 114. In alternative embodiments, power source 130 may deliver power to hinge 122 when PWB 114 exceeds a certain temperature. In certain embodiments, some of the PWBs 114 may have temperature controlled door features (as previously described with respect to FIG. 3), while other PWBs 114 may have door features (as previously described with respect to FIG. 5), arranged within a single remote power unit.

### Discussion of Possible Embodiments

The following are non-exclusive descriptions of possible embodiments of the present invention.

A remote power unit has an inlet duct arranged on a housing and configured to receive cooling air. A plurality of slots are each configured to hold a printed wiring board. A plurality of printed wiring boards are held in at least some of the plurality of slots. An outlet duct is arranged opposite the printed wiring boards from the inlet duct, forming a path for cooling air to flow from the inlet duct along the printed wiring boards to the outlet duct. A plurality of doors each has a shape memory element. Each of the doors are arranged on one of the plurality of slots.

The remote power unit of the preceding paragraph can optionally include, additionally and/or alternatively, any one or more of the following features, configurations and/or additional components:

The shape memory element may be a thermal shape memory element having a transition temperature.

Each of the shape memory elements may comprise a shape memory coil.

The shape memory coil may be a hinge.

Each of the shape memory elements may comprise a Nitinol alloy.

The plurality of doors may be configured to be in the open position when the shape memory element is above a transition temperature, and closed when the thermal memory element is below the transition temperature.

Each of the shape thermal memory elements may be in thermal contact with an associated printed wiring board.

The remote power unit may also include a lead connecting each of the shape memory elements to a power source. The power source may be configured to deliver power to the shape memory element via the lead when an associated printed wiring board exceeds a threshold temperature. The power source may be configured to deliver power to the shape thermal memory element via the lead when the printed wiring board delivers power to a remote load.

According to a further embodiment, a method for cooling a printed wiring that generates heat while operating, the printed wiring board being housed in a remote power unit, includes providing a cooling airstream within the remote power unit. The method further includes thermally coupling a shape thermal memory element having a transition temperature to the printed wiring board, the shape thermal memory element being responsive to a temperature that exceeds the transition temperature to open a door attached thereto to allow the cooling airstream to flow around the printed wiring board.

The method of the preceding paragraph can optionally include, additionally and/or alternatively, any one or more of the following features, configurations, steps, and/or additional components:

The printed wiring board may be one of a plurality of printed wiring boards housed in the remote power unit.

According to a further embodiment, a method for cooling a printed wiring board housed in a remote power unit, includes providing a cooling airstream within the remote power unit. The method further includes distributing power via the printed wiring board. The method further includes powering a lead connected to a shape memory element having a transition temperature to open a door attached thereto to allow the cooling airstream to flow around the printed wiring board.

The method of the preceding paragraph can optionally include, additionally and/or alternatively, any one or more of the following features, configurations, steps, and/or additional components:

Powering the lead may cause resistive heating in the shape thermal memory element.

The shape memory element may be a thermal shape memory element, and powering the lead may cause resistive heating of the thermal shape memory element.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A remote power unit comprising:
an inlet duct arranged on a housing and configured to receive cooling air;
a plurality of slots each configured to hold a printed wiring board;
a plurality of printed wiring boards held in at least some of the plurality of slots;
an outlet duct arranged opposite the printed wiring boards from the inlet duct, forming a path for cooling air to flow from the inlet duct along the printed wiring boards to the outlet duct; and
a plurality of doors each having a shape memory element, each of the doors arranged on one of the plurality of slots.

2. The remote power unit of claim 1, wherein the shape memory element is a thermal shape memory element having a transition temperature.

3. The remote power unit of claim 1, wherein each of the shape memory elements comprises a shape memory coil.

4. The remote power unit of claim 3, wherein the shape memory coil is a hinge.

5. The remote power unit of claim 1, wherein each of the shape memory elements comprises a Nitinol alloy.

6. The remote power unit of claim 1, wherein the plurality of doors are configured to be in the open position when the shape memory element is above a transition temperature, and the plurality of doors are configured to be in the closed position when the thermal memory element is below the transition temperature.

7. The remote power unit of claim 6, wherein each of the shape thermal memory elements is in thermal contact with an associated printed wiring board.

8. The remote power unit of claim 1, and further comprising a lead connecting each of the shape memory elements to a power source.

9. The remote power unit of claim 8, wherein the power source is configured to deliver power to the shape memory element via the lead when an associated printed wiring board exceeds a threshold temperature.

10. The remote power unit of claim 7, wherein the power source is configured to deliver power to the shape thermal memory element via the lead when the printed wiring board delivers power to a remote load.

11. A method for cooling a printed wiring that generates heat while operating, the printed wiring board being housed in a remote power unit, the method comprising:
providing a cooling airstream within the remote power unit; and
thermally coupling a shape thermal memory element having a transition temperature to the printed wiring board, the shape thermal memory element being responsive to a temperature that exceeds the transition temperature to open a door attached thereto to allow the cooling airstream to flow around the printed wiring board.

12. The method of claim 11, wherein the printed wiring board is one of a plurality of printed wiring boards housed in the remote power unit.

13. A method for cooling a printed wiring board housed in a remote power unit, the method comprising:
providing a cooling airstream within the remote power unit;
distributing power via the printed wiring board;
powering a lead connected to a shape memory element having a transition temperature to open a door attached thereto to allow the cooling airstream to flow around the printed wiring board.

14. The method of claim 13, wherein powering the lead causes resistive heating in the shape thermal memory element.

15. The method of claim 13, wherein the shape memory element is a thermal shape memory element, and powering the lead causes resistive heating of the thermal shape memory element.
